(19) United States
(12) Patent Application Publication
(10) Pub. No.: US 2009/0283663 A1
(43) Pub. Date: Nov. 19, 2009

(54) SOLID-STATE IMAGING DEVICE AND DRIVING METHOD THEREOF

(75) Inventors: Rie RYUZAKI, Kyoto (JP); Masashi MURAKAMI, Kyoto (JP); Yutaka ABE, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/466,449

(22) Filed: May 15, 2009

(30) Foreign Application Priority Data
May 19, 2008 (JP) 2008-131068

(51) Int. Cl. H01L 27/00; G01T 1/24

(52) U.S. Cl. 250/208.1; 250/370.08

(57) ABSTRACT

It is an object of the present invention to provide a solid-state imaging device capable of significantly improving the signal readout characteristics of the pixel compared to the conventional technologies at low cost, without degrading the reliability, and a driving method thereof. The solid-state imaging device according to the present invention is a solid-state imaging device which includes a drive circuit, and the drive circuit includes: a P-channel transistor and a N-channel transistor which include gates connected to an output of the scanning circuit, and which include drains that are connected to each other, and a connecting point of the drains is connected to the control signal line, a switch which switches between VHI and DVDD to be supplied to a source of the P-channel transistor, and a switch which switches between VLOW and VGND to be supplied to a source of the N-channel transistor.

### BACKGROUND OF THE INVENTION

(1) Field of the Invention

The present invention relates to a solid-state imaging device and a driving method thereof.

(2) Description of the Related Art

Metal Oxide Semiconductor (MOS) image sensors are solid-state imaging devices that operate at low electric power and are low in power consumption. The standard Complementary Metal Oxide Semiconductor (CMOS) process can be used for manufacturing the MOS image sensors. Thus, the MOS image sensors can be manufactured at lower cost than the Charge Coupled Device (CCD), which makes them beneficial image sensors. Furthermore, it is possible to mount a MOS image sensor together with a logic circuit using the standard CMOS process. This allows on-chip integration aiming for mounting the MOS image sensor to a module which requires high-speed data processing.

In recent years, with the advantages of low power consumption and low cost, the MOS image sensors have been used for various purposes. For example, the MOS image sensors have been used in a wide range of area such as digital still cameras, digital video cameras, and on-vehicle cameras. Among these areas, imaging devices require especially high image quality.

Imaging devices are often used for capturing images in the occasions where there are large luminance differences, for example, in and out of tunnel in the case of on-vehicle cameras, inside the room and outside the window in the case of digital still cameras. Accordingly, it is necessary for the imaging devices to have wide dynamic range characteristics. Furthermore, when capturing a moving object or capturing images at high speed, low afterimage characteristics is necessary.

FIG. 6 shows a structure of a general MOS image sensor. The MOS image sensor includes the imaging area 101 where the pixel cells 11 are arranged in rows and columns. It should be noted that although FIG. 6 shows the three-transistor pixel cells (a type where the pixel cell is composed of three transistors) 11, other pixel structures such as a four-transistor pixel cell (a type where the pixel cell is composed of four transistors) do not affect the following argument. Furthermore, the MOS image sensor includes the scanning circuit 102 which scans the row of the pixel cells 11 and the drive circuit 103 for driving a pulse control signal generated in the scanning circuit 102 and inputting the pulse control signal to the pixel cells 11 on the selected row.

FIG. 7 shows the structure of the pixel cell 11. The pixel cell 11 includes the photodiode pd, the transfer transistor m1, the floating diffusion fd, the reset transistor m2, and the amplifier transistor m3. Each of the transistors is driven by the supply voltage AVDD shared with a peripheral analog circuit and the ground voltage VGND. Usually, the supply voltage AVDD used for analog circuit is set to a range where the analog characteristics can be fully taken advantage of, and low in power consumption, and within a voltage or a range at a constant distance from the range of the voltage supply regulator. The maximum rated voltage of the transistors used for the analog circuit is set to a voltage ensuring the reliability of the transistors, and AVDD is supplied within the maximum rated voltage.

A row scanning circuit and a column scanning circuit are provided outside the imaging area 101. The column scanning circuit includes the scanning circuit 102 and the drive circuit 103. A pulse signal in response to a reference clock is input to the drive circuit 103 of the desired row from the scanning circuit 102, the pulse control signal driven by the drive circuit 103 is supplied to each transistor in the imaging area 101 via the control signal lines RS and TX, and the pixel signals from the pixel cells 11 are sequentially read. The pixel signals read out of the pixel cells 11 is output to the column signal line 30 by the constant current source transistor m4.

In recent years, various approaches have been made in order to improve on the characteristics such as the dynamic range and the afterimages described above by modifying the manufacturing process, for example. Modifying the process improves the saturation charge of the photodiode pd and the transfer efficiency of electric charges. However, when the driving voltage of the pixel cells 11 is within the range of AVDD/VGND as in the conventional technology, the improvement on the characteristics are not fully utilized. In response to this problem, there has been an approach expanding the driving voltage range of the pixel cells 11 in order to improve on the signal readout characteristics from the pixel cells 11.

FIGS. 8A and 8B show the potential distribution on the pixel cell 11 (cross section A-B in FIG. 7). Note that FIG. 8A shows the potential distribution when the transfer transistor m1 is off, and FIG. 8B shows the potential distribution when the transfer transistor m1 is on. The solid lines indicate the potential distribution of the pixel cell 11 when driven in the conventional voltage range. The broken lines indicate the potential distribution of the pixel cell 11 when the driving voltage range is expanded.

In the case where the gate voltage of the transfer transistor m1 when the transfer transistor m1 is switched on is not set high enough (the solid line shown in FIG. 8B), there will be remaining non-transferred charge in the photodiode pd, which causes the afterimage. Furthermore, in the case where the gate voltage of the reset transistor m2 when the reset transistor m2 is switched on is not high enough (the solid lines in FIG. 8B), the charge which is noise component remains in the floating diffusion fd, causing the deterioration in the S/N characteristic and the afterimages. Furthermore, if it is possible to set the gate voltage of the transfer transistor m1 and the reset transistor m2 when they are switched off at a fully low voltage (the broken lines in FIG. 8A), more charge can be accumulated. This improves on the dynamic range and the S/N characteristics. Thus, setting the gate voltage of the transfer transistor m1 and the reset transistor m2 when switched on higher and setting the gate voltages lower when they are switched off improves on the signal readout characteristics from the pixel cells 11.

Note that the technology disclosed in Patent Reference 1 (Japanese Unexamined Patent Application Publication (Translation of PCT Application) No. 2006-527973) is a technology for expanding the driving voltage range.

### SUMMARY OF THE INVENTION

As described above, the method for decreasing the off voltage and increasing on voltage of the pulse control signal supplied to the transfer transistor and the reset transistor of the pixel cell in order to improve on the signal readout characteristics from the pixel cells has been tried. When inputting the pulse control signals from the timing generator and others to the pixel cell, it is necessary to amplify the current before inputting the pulse control signal to the pixel cell in order to drive the load of many gates and wiring. There are two types of drive circuits for amplifying the current, namely the inverter (inverted) type as shown in FIG. 9A and buffer (non-inverted) type. However, the buffer type drive circuit can be composed by arranging two inverter circuits. Accordingly, in this specification, description will be made for the inverter-type driving circuit only.

In the drive circuit in FIG. 9A, the input signal Vin shown in FIG. 9B (a) that performs pulse operation within the voltage range between the first voltage VHI and the second voltage VLOW (VHI>VLOW) is input to the gate of the transistor, and the output signal Vout as shown in FIG. 9B (b) is output. When the level of the input signal is VHI, the N-channel transistor Tr2 is switched on at the same time as the P-channel transistor Tr1 of the drive circuit is switched off. Accordingly, VLOW is supplied to the output line. Furthermore, when the input signal level is VLOW, the N-channel transistor Tr2 is switched off at the same time as the P-channel transistor Tr1 is switched on. Accordingly, VHI is supplied to the output line.

In order to expand the driving voltage range, VHI supplied to the drive circuit is increased, and VLOW supplied to the drive circuit is decreased. However, when the input signal range is expanded to a value over a certain value, there is a problem that the voltage exceeding the maximum rated voltage is applied between the gate and the drain or between the gate and the source of a transistor in the drive circuit. The following describes a specific example.

For example, it is assumed that the voltage range of the normal control signal, which is 0 to 3.3 V, is changed to −1 to 4 V in order to improve readout characteristics from the pixel cells as described above. It is also assumed that the maximum rated voltage of the transistor is 4.5 V. VHI=4 V and VLOW=−1V are input to the input terminal of the drive circuit in FIG. 9A, VHI=4 V is selected as a source voltage to be supplied to the source of the P-channel transistor Tr1, and VLOW=−1 V is selected as the source voltage to be supplied to the source of the N-channel transistor Tr2. When VHI=4 V is applied to the input terminal, the P-channel transistor Tr1 is switched off, at the same time as the N-channel transistor Tr2 is switched on. Accordingly, VLOW=−1 V is supplied to the output line. Here, 4 V, 4 V, and −1 V are respectively applied to the gate, the source, and the drain of the P-channel transistor Tr1, which makes the applied voltage between the gate and the drain 5 V. This exceeds the maximum rated voltage of the transistor, which is 4.5 V. Here, 4 V, −1 V, and −1 V are respectively applied to the gate, the source, and the drain of the N-channel transistor Tr2 as well, which makes the applied voltage between the gate and the drain and between the gate and source 5 V. This is higher than the maximum rated voltage of the transistor, or 4.5 V. Similarly, when −1 V is applied to the input terminal of the drive circuit shown in FIG. 9A, the voltage higher than the maximum rated voltage is applied between the gate and the drain and between the gate and the source of the P-channel transistor Tr1, and between the gate and the drain of the N-channel transistor Tr2. Application of the voltage higher than the maximum rated voltage between the gate and the source and between the gate and the drain of the transistor is highly likely to break the transistor, which causes a significant problem in terms of the reliability of the transistor.

One plausible method for solving this problem is to increase the breakdown voltage of the gate oxidized film in the transistor. However, providing a transistor with a gate oxidized film having a breakdown voltage different from those of the peripheral transistors means, in addition to the development cost, anything but adding a new process or increasing the number of masks in the manufacturing process, which in creases the manufacturing cost.

There has been no previous report that the drive circuit which drives the transistor of the pixel at a voltage range exceeding the maximum rated voltage of the transistor of the pixel cell is implemented without using a transistor with a gate oxidized film having a breakdown voltage different from the breakdown voltage of the transistors in the periphery of the drive circuit, but by modifying the circuit structure.

In view of the foregoing problems, it is an object of the present invention to provide a solid-state imaging device and a driving method of the solid-state imaging device which significantly improve the signal readout characteristics from the pixels compared to the conventional technology at low cost, without degrading the reliability.

In order to achieve the abovementioned object, the solid-state imaging device according to the present invention is a solid-state imaging device including: pixels which are arranged in rows and columns, and each of which includes a photodiode; column signal lines which are provided corresponding to the columns of the pixels, and each of which transmits, in a column direction, a pixel signal corresponding to a charge generated in each of the photodiodes; a generating unit which drives the pixels and to generate a control signal for outputting the pixel signal from the pixels to the column signal lines; a drive unit which drives the control signal generated by the generating unit; and a control signal line which connects the drive unit and the pixels, and supplies the control signal driven by the drive unit to the pixels, in which the drive unit includes: a first P-channel transistor and a first N-channel transistor which include gates connected to an output of the generating unit, and which include drains that are connected to each other, and a connecting point of the drains is connected to the control signal line; a first switch which switches between first power and second power to be supplied to a source of the first P-channel transistor; and a second switch which switches between third power and fourth power to be supplied to a source of the first N-channel transistor.

This allows switching the power to be supplied to the source of the first P-transistor or the source of the first N-channel transistor, according to the potential of the control signal line, in other words, the potential of the connecting point of the drains of the first P-channel transistor and the first N-channel transistor in the drive unit Supplying the power after switching allows the voltage level applied between the gate and the drain or between the gate and the source of the first P-channel transistor or the first N-channel transistor not to exceed the maximum rated voltage of the transistor. Therefore, it is possible to implement a solid-state imaging device capable of significantly improving the signal readout characteristics from the pixel compared to the conventional technologies at low cost and without degrading the reliability.

Furthermore, the present invention may be that the first switch switches between the first power and the second power to be supplied to the source of the first P-channel transistor based on the control signal, and the second switch switches between the third power and the fourth power to be supplied to the source of the first N-channel transistor based on the control signal.

This allows switching the power to be supplied to the source of the first P-channel transistor or the first N-channel transistor at a suitable time in connection with the control signal that drives the pixel. Accordingly, in an inverter circuit which is a general drive circuit, it is possible not to apply a voltage exceeding the maximum rated voltage to a transistor in the inverter circuit according to the input signal level to the inverter.

Furthermore, the present invention may include the first switch which includes: a second P-channel transistor which has a source connected to the first power and which has a drain connected to the source of the first P-channel transistor; and a third P-channel transistor which has a source connected to the second power and which has a drain connected to the source of the first P-channel transistor, and the second switch which includes: a second N-channel transistor which has a source connected to the third power and which has a drain connected to the source of the first N-channel transistor; and a third N-channel transistor which has a source connected to the fourth power and which has a drain connected to the source of the first N-channel transistor.

Here, it is preferable that gates of the second and third P-channel transistors are respectively connected to an output of the generating unit, and the drive unit further includes a first signal voltage conversion element inserted between the output of the generating unit and the gates of the second and third P-channel transistors.

Similarly, it is also preferable that gates of the second and third N-channel transistors are respectively connected to an output of the generating unit, and the drive unit further includes a second signal voltage conversion element inserted between an output of the generating unit and the gates of the second and third N-channel transistors.

Furthermore, it is also preferable that the drive unit further includes a third signal voltage conversion element inserted between an output of the generating unit and the gates of the first N-channel transistor and the first P-channel transistor.

This allows driving the pixels and controlling power switching with one control signal without using the control signals having different voltage levels, and with the control signal at a desired voltage level.

Furthermore, it is also preferable that gates of the second and third P-channel transistors are respectively connected to an output of the generating unit, and the drive unit further includes an inverter element inserted between the output of the generating unit and the gate of the second P-channel transistor.

Similarly, it is preferable that gates of the second and third N-channel transistors are respectively connected to an output of the generating unit, and the drive unit further includes an inverter element inserted between the output of the generating unit and the gate of the second N-channel transistors.

Furthermore, it is also preferable that the drive unit further includes an inverter element inserted between the output of the generating unit and the gates of the first N-channel transistor and the first P-channel transistors.

With this, it is possible to generate a logically-inverted control signal. This facilitates the control for switching two power with one control signal.

According to the present invention, it is possible to expand the voltage range of the control signal to the range exceeding the maximum rated voltage of the transistor in the drive circuit without applying the voltage exceeding the maximum rated voltage to any of the transistors in the drive circuit which drives the control signal for driving the pixel without an increase in the number of manufacturing process and the number of masks. Therefore, it is possible to significantly improve the signal readout characteristics from the pixels without damaging the reliability, and thus it is possible to achieve a high-image quality imaging device while assuring the quality.

### FURTHER INFORMATION ABOUT TECHNICAL BACKGROUND TO THIS APPLICATION

The disclosure of Japanese Patent Application No. 2008-131068 filed on May 19, 2008 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 shows the schematic structure of the solid-state imaging device according to the embodiments of the present invention;

FIG. 2A shows the schematic structure of the drive circuit which outputs a pulse control signal for driving each transistor in the pixel cell;

FIG. 2B shows the schematic structure of the drive circuit which outputs a pulse control signal for driving each transistor in the pixel cell;

FIG. 2C shows the schematic structure of the drive circuit which outputs a pulse control signal for driving each transistor in the pixel cell;

FIG. 3 shows the potential of the output signal and the input signal from and to the drive circuit and in each node;

FIG. 4A shows a specific structure of the drive circuit in the first example;

FIG. 4B shows a magnitude relationship and phasic relationship of output signal, input signal, and voltage of the pulse control signal which drives the switch transistor of the drive circuit;

FIG. 5A shows a specific structure of the drive circuit in the second example;

FIG. 5B shows the potential of the output signal, input signal from and to the drive circuit and in each node;

FIG. 6 shows the structure of the MOS image sensor in general;

FIG. 7 shows the structure of the pixel cell;

FIG. 8A shows the potential distribution in the pixel cell (in the cross-section A-B in FIG. 7);

FIG. 8B shows another potential distribution in the pixel cell (in the cross-section A-B in FIG. 7);

FIG. 9A shows the structure of a drive circuit in general; and

FIG. 9B shows the output signal and the input signal from and to the drive circuit.

### DESCRIPTION OF THE PREFERRED EMBODIMENT(S)

The best embodiments for implementing the present invention will be described hereafter with reference to the drawings.

Note that, although the imaging area is composed of 2×2 pixel cells for the simplicity of explanation in the embodiments, this does not limit the number of the pixel cells. Accordingly, the embodiments can be applied to any number of pixel cells.

It should be also noted that the embodiments can be applied not only to the pixel cell composed of three transistors without the select transistor as in the embodiments, but also to the pixel cells having different circuit structures, for example, to the pixel cells composed of four transistors with a select transistor and to the pixel cells composed of three transistors without a transfer transistor that allows nondestructive readout.

Furthermore, it should be noted that although the drive circuit is described as an inverter (inverted) type in the embodiments, no description for the buffer (non-inverted) type will be made, since the input signal inverted in advance will be input to the drive circuit, when the drive circuit is a buffer (non-inverted) type.

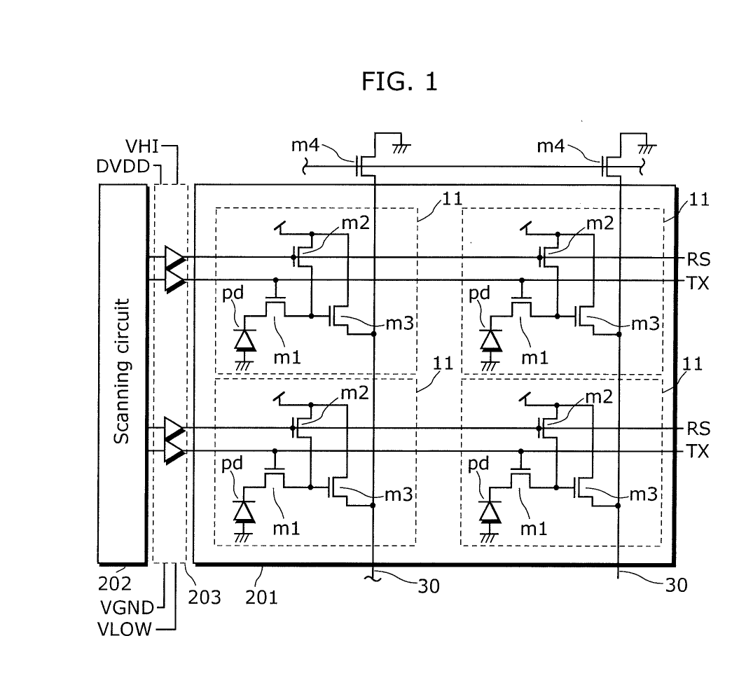

FIG. 1 shows the schematic structure of the solid-state imaging device according to the embodiments.

The solid-state imaging device is a MOS image sensor, and includes the imaging area 201 where the unit pixel cells 11 each of which includes a photodiode are arranged in rows and columns. Furthermore, the solid-state imaging device includes the scanning circuit 202 which scans the rows of the pixel cells 11, the drive circuit 203 for driving the pulse control signal generated in the scanning circuit 202 and for inputting the driven pulse control signal to the rows of the pixel cells 11, the column signal line 30 provided corresponding to the columns of the pixel cells 11 and for transmitting the pixel signal corresponding to the charge generated in each of the photodiodes corresponding to the intensity of the incident light in the column direction, and the control signal lines RS and TX which connect the drive circuit 203 and the pixel cells 11 and which supply the pulse control signal driven by the drive circuit 203. The pulse control signal is a signal which drives the pixel cells 11, and causes the pixel cells 11 to output the pixel signals to the column signal line 30. The source voltage supplied to the conventional drive circuit includes two types, namely, AVDD and VGND. Four types of the source voltages, DVDD, VHI, VGND, and VLOW are supplied in the solid-state imaging device according to the embodiments.

Note that the scanning circuit 202 is an example of the generating unit according to the present invention, and the drive circuit 203 is an example of the driving unit according to the present invention.

A row scanning circuit and a column scanning circuit are provided outside the imaging area 201. The column scanning circuit includes the scanning circuit 202 and the drive circuit 203, and the scanning circuit 202 inputs the pulse control signal in response to the reference clock to the drive circuit 203 in the desired row. The pulse control signal whose current was amplified by the drive circuit 203 is supplied to each transistor in the pixel cells 11, and the signals are sequentially read out of the pixel cells 11. The pixel signals read out of the pixel cells 11 is output to the column signal line 30 by the constant current source transistor m4.

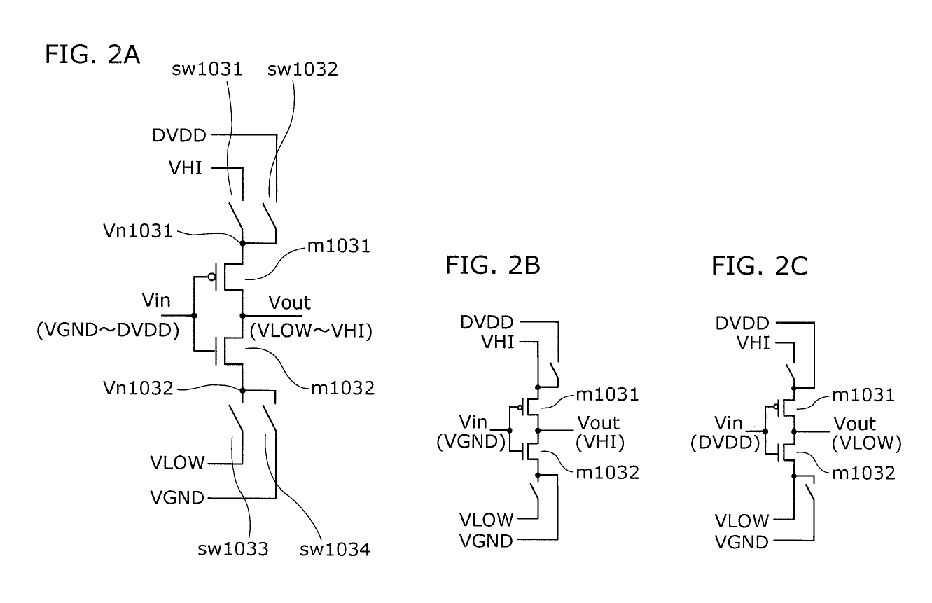

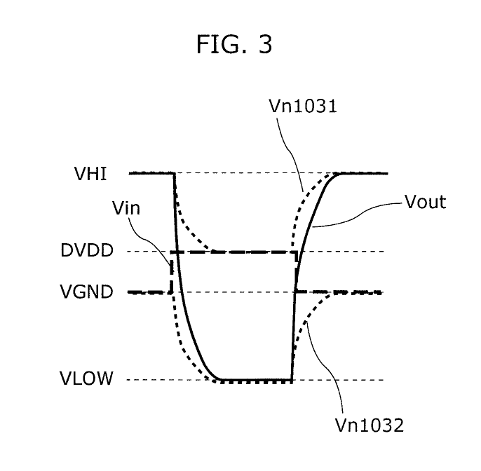

FIG. 2A to 2C show the schematic structure of the drive circuit 203 which outputs the pulse control signals for driving each of the transistors in the pixel cells 11. Note that FIGS. 2A to 2C shows the schematic structure of the drive circuit 203 which drives one of the control signal lines RS or TX. Furthermore, FIG. 2B shows the circuit structure when the pulse control signal (output signal) Vout output from the drive circuit 203 is in Hi voltage (VHI), and FIG. 2C shows the circuit structure when the output signal Vout is in Low voltage (VLOW). FIG. 3 shows the potential in the output signal Vout from the drive circuit 203, the pulse control signal (input signal) Vin input to the drive circuit 203, and in the nodes Vn1031 and Vn1032 in FIGS. 2A to 2C.

The drive circuit 203 includes the P-channel transistor m1031 and the N-channel transistor m1032 respectively include the gates connected to the output of the scanning circuit 202, the drains are mutually connected, and the connecting point in the drains are connected to the control signal line RS or TX.

The drive circuit 203 includes the switches sw1031 and sw1032 for switching between “VHI” and “DVDD” to be supplied to the source of the P-channel transistor m1031, and the switches sw1033 and sw1034 for switching between “VLOW” and “VGND” to be supplied to the source of the N-channel transistor m1032. To put it differently, the drive circuit 203 includes the switches sw1031, sw1032, sw1033, and sw1034 for switching the voltages supplied to the nodes Vn1031 and Vn1032 respectively in the source side of the P-channel transistor m1031 and the N-channel transistor m1032 according to whether the output signal Vout is “VHI” or “VLOW”. The drive circuit 203 converts the input signal Vin to “DVDD” and “VGND” to the output signal Vout of “VHI” (DVDD<VHI<the maximum rated voltage) and of “VLOW” (DVDD−the maximum rated voltage<VLOW<VNGD). Here, switching the voltages in the source sides of the P-channel transistor m1031 and the N-channel transistor m1032 prevents the voltage exceeding the maximum rated voltage applied to the P-channel transistor m1031 and the N-channel transistor m1032.

Note that “VHI” is an example of the first power according to the present invention, “DVDD” is an example of the second power according to the present invention, “VLOW” is an example of the third power according to the present invention, and “VGND” is an example of the fourth power according to the present invention. Furthermore, the P-channel transistor m1031 is an example of the first P-channel transistor according to the present invention, and the N-channel transistor m1032 is an example of the first N-channel transistor according to the present invention.

In the solid-state imaging device having the structure described above, the output signal Vout is applied to the gates of the transfer transistor m1 and the reset transistor m2 of the pixel cells 11 through the control signal lines RS and TX. When the light enters the photodiode pd in the pixel cells 11, charge is generated through photoelectric conversion, and the charge is accumulated therein. During the accumulation time of the charge, the gate of the transistor m1 is switched off. According to the solid-state imaging device of the embodiments, Low voltage of the output signal Vout is VLOW, and is lower than the conventional VGND, and the gate voltage of the transfer transistor m1 when switched off can be lower than the conventional technology. Thus, the amount of change that can be accumulated in the photodiode pd can be increased.

Furthermore, in the beginning of the charge readout period of the pixel cells 11, the charge accumulated in the floating diffusion is reset by switching on the reset transistor m2 while the transfer transistor m1 is switched off. According to the solid-state imaging device of the embodiments, the Hi voltage of the output signal Vout is VHI, which is higher than the conventional AVDD, and the gate voltage of the reset transistor m2 when resetting the charge can be set to a level higher than the conventional technology. Thus, it is possible to reduce the amount of charge that remains in the floating diffusion compared to the conventional technology.

Furthermore, the charge accumulated in the photodiode pd can be transferred to the floating diffusion by switching off the reset transistor m2 and by switching on the transfer transistor m1. According to the solid-state imaging device of the embodiments, the Hi voltage of the output signal Vout is VHI, which is higher than the conventional AVDD, and the gate voltage of the transfer transistor m1 when transferring the charge can be set to a voltage higher than the conventional technology. Thus, it is possible to transfer the charge accumulated in the photodiode pd to the floating diffusion without leaving the charge.

Furthermore, the charge transferred to the floating diffusion is amplified by an amplifier after the conversion to voltage, and read out of the imaging area 201.

As described above, according to the solid-state imaging device of the embodiments, it is possible to reduce the gate voltage of the transfer transistor m1 when switched off, and to increase the amount of saturation charge of the photodiode pd. This achieves wide dynamic range characteristics.

Furthermore, according to the solid-state imaging device according to the embodiments, it is possible to increase the gate voltage of the transfer transistor m1 and the reset transistor m2 when switched on. Thus, the remaining amount of charge in the photodiode pd and the floating diffusion decreases, compared to the conventional technology, and thus a lower afterimage characteristic can be achieved. To put it differently, it is possible to increase the amount of readout charge from the pixel cells 11, and to reduce the afterimage. Thus, it is possible to improve the S/N ratio of the pixel signal, and significantly improves the image quality. This slightly increases the circuit size of the driving stage in the drive circuit. However, the increase can be ignored since the increment in the entire chip as the solid-state imaging device is extremely small. Rather, implementing a high image quality solid-state imaging device is highly beneficial while ensuring the quality without the new manufacturing process or increase in the number of masks, in other words, without any cost increase.

### FIRST EXAMPLE

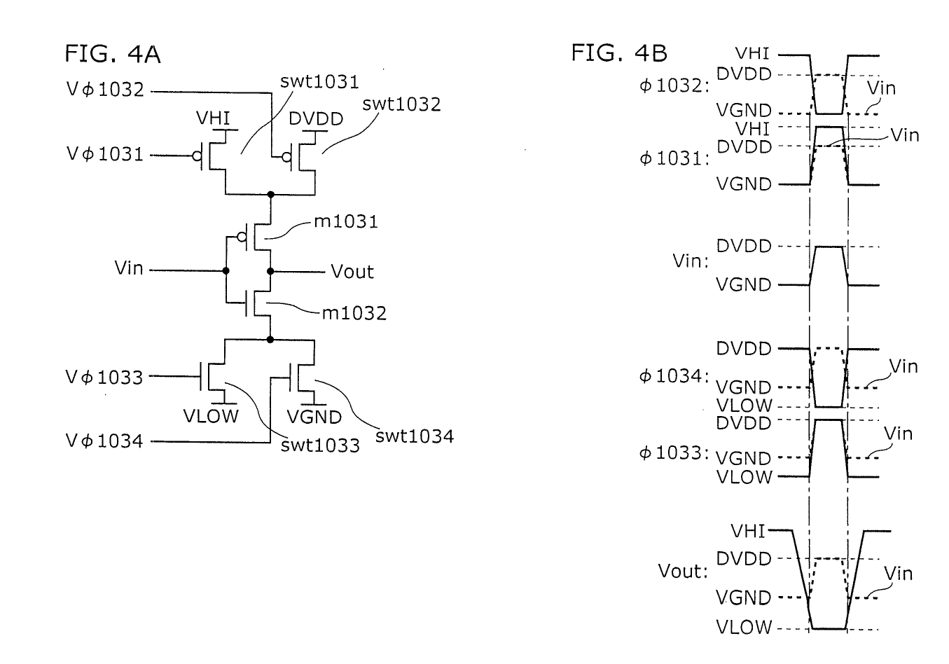

FIG. 4A shows a specific structure of the drive circuit 203 in the first example. FIG. 4B shows a magnitude relationship and phasic relationship of the voltage of the pulse control signals ◯1031 to 1034 which drives the switch transistors swt1031 to swt1034 of the drive circuit 203, output signal Vout, and input signal Vin.

In the drive circuit 203, the drive inverter which drives each transistor in the pixel cells 11 is composed of the P-channel transistor m1031 and N-channel transistor m1032, and switch transistors swt1031 to swt1034. The switches sw1031, sw1032, sw1033 and sw1034 in FIGS. 2A to 2C respectively correspond to the switch transistors swt1031, swt1032, swt1033, and swt1034.

The switch transistor swt1031 has a source connected to “VHI” and a drain connected to the source of the P-channel transistor m1031. The switch transistor swt1032 has a source connected to “DVDD” and a drain connected to the source of the P-channel transistor m1031. The switch transistor swt1033 has a source connected to “VLOW” and a drain connected to the source of the N-channel transistor m1032. The switch transistor swt1034 has a source connected to “VGND” and a drain connected to the source of the N-channel transistor m1032.

Note that the switch transistors swt1031 and swt1032 are examples of the first switch according to the present invention, and the switch transistors swt1033 and swt1034 are examples of the second switch according to the present invention. To put it differently, the switch transistor swt1031 is an example of the second P-channel transistor according to the present invention, and the switch transistor swt1032 is an example of the third P-channel transistor. Furthermore, the switch transistor swt1033 is an example of the second N-channel transistor according to the present invention, and the switch transistor swt1034 is an example of the third N-channel transistor according to the present invention.

In the drive circuit 203, the pulse control signals ◯1031 to ◯1034 as shown in FIG. 4B are input to the switch transistors swt1031 to swt1034, and switching operation is performed in connection with the signal output Vout. Usually, the pulse control signals ◯1031 to ◯1034 are generated by providing a timing generator such as Field Programmable Gate Array (FPGA) outside the chip to input the pulse control signals to the sensor chip, or by providing the timing generator within the chip to generate the pulse control signals, in the first example, it does not matter how the pulse control signals ◯1031 to ◯1034 are generated.

Note that, although the Hi voltage of the input signal Vin is set at the power source voltage DVDD for digital circuit, it may also be the power source voltage AVDD for analog circuits. The power source voltage DVDD for digital circuits (1.2 V, for example) and the power source voltage AVDD for analog circuits (3.3 V, for example) are generally used for one circuit in an analog-digital hybrid circuit. For example, it is common to use the power source voltage for digital circuits in a logic circuit in the column scanning circuit, and shifts to the voltage for analog circuits in the drive circuit before the pixel cells 11. However, when the Hi voltage of the input signal Vin is set at AVDD, it is necessary to set the voltage supplied to the source of the switch transistor swt1032 to AVDD at the same time.

The power source voltage DVDD for digital circuits and the high voltage VHI for driving the pixel cell 11 are supplied to the source of the P-channel transistor m1031 of the drive circuit 203 as the power source voltage. On the other hand, the ground voltage VGND and the low voltage VLOW for driving the pixel cell 11 are supplied to the source of the N-channel transistor m1032 on the drive circuit 203 as the power source voltage.

When VHI is selected as the power source voltage supplied to the source of the P-channel transistor m1031 on the drive circuit 203, the P-channel transistor m1031 is not sufficiently switched off if the input signal Vin is DVDD. In the same manner, when VLOW is selected as the power source voltage supplied to the source of the N-channel transistor m1032 in the drive inverter, the N-channel transistor m1032 is not sufficiently switched off if the input signal Vin is VGND. Accordingly, it is necessary to set the voltages VHI and VLOW at a voltage level where the P-channel transistor m1031 and the N-channel transistor m1032 are switched off.

It is assumed that the input signal Vin is VGND in the drive circuit 203 in FIG. 4A.

Here, VHI is selected as the power source voltage connected to the source of the P-channel transistor m1031 in the drive circuit 203. More specifically, the pulse control signal ◯1031 is set at VGND, and the pulse control signal 1032 is set at VHI so that the switch transistor swt1031 is switched on, and that the switch transistor swt1032 is switched off.

At the same time, VGND is selected as the power source voltage connected to the source of the N-channel transistor m1032 in the drive circuit 203. More specifically, the pulse control signal ◯1033 is set at VLOW, and the pulse control signal 01034 is set at DVDD so that the switch transistor swt1033 is switched off, and the switch transistor swt1034 is switched on.

In the abovementioned state, VHI is supplied from the P-channel transistor m1031 as the output signal Vout. With respect to the voltage applied to each transistor, the gate-source voltage and the gate-drain voltage of the switch transistor swt1031 are both at VHI. The gate-source voltage of the switch transistor swt1032 is (DVDD-VHI), and the gate-drain voltage of the switch transistor swt1032 is 0 V. The gate-source voltage and the gate-drain voltage of the P-channel transistor m1031 are both VHI. The gate-source voltage of the switch transistor swt1033 is 0 V, and the gate-drain voltage is VLOW. The gate-source voltage and the gate-drain voltage of the switch transistor swt1034 are both DVDD. The gate-source voltage of the N-channel transistor m1032 is 0 V, and the gate-drain voltage of the N-channel transistor m1032 is VHI. Therefore, the voltage exceeding the maximum rated voltage is not applied to any of the transistors.

Furthermore, it is assumed that the input signal Vin is DVDD in the drive circuit 203 in FIG. 4A.

Here, DVDD is selected as the power source voltage connected to the source of the P-channel transistor m1031 in the drive circuit 203. More specifically, the pulse control signal ◯1031 is set at VHI, and the pulse control signal ◯1032 is set at VGND so that the switch transistor swt1031 is switched off, and the switch transistor swt1032 is switched on.

At the same time, VLOW is selected as the power source voltage connected to the source of the N-channel transistor m1032 in the drive circuit 203. More specifically, the pulse control signal ◯1033 is set at DVDD, and the pulse control signal ◯1034 is set at VLOW so that the switch transistor swt1033 is switched on, and the switch transistor swt1034 is switched off.

In the abovementioned state, VLOW is supplied from the N-channel transistor m1032 as the output signal Vout. With respect to the voltage applied to each transistor, the gate-source voltage of the switch transistor swt1031 is 0 V, and the gate-drain voltage of the switch transistor swt1031 is (VHI-DVDD). The gate-source voltage and the gate-drain voltage of the switch transistor swt1032 are both DVDD. The gate-source voltage of the P-channel transistor m1031 is 0 V, and the gate-drain voltage of the P-channel transistor m1031 is (DVDD-VLOW). The gate-source voltage and the gate-drain voltage of the switch transistor swt1033 are both (DVDD-VLOW). The gate-source voltage of the switch transistor swt1034 is VLOW, and the gate-drain voltage of the switch transistor swt1034 is 0 V. The gate-source voltage and the gate-drain voltage of the N-channel transistor m1032 are both (DVDD-VLOW). Therefore, the voltage exceeding the maximum rated voltage is not applied to any of the transistors.

As described in the drive circuit 203 according to the first example, it is possible to expand the voltage range of the pulse control signal that can be applied to the pixel cells 11, without applying the voltage exceeding the maximum rated voltage to between the terminals of any transistor in the drive circuit 203. To put is differently, it is possible to expand the voltage range to the range of (2×maximum rated voltage−DVDD) compared to the range of the conventional maximum rated voltage.

### SECOND EXAMPLE

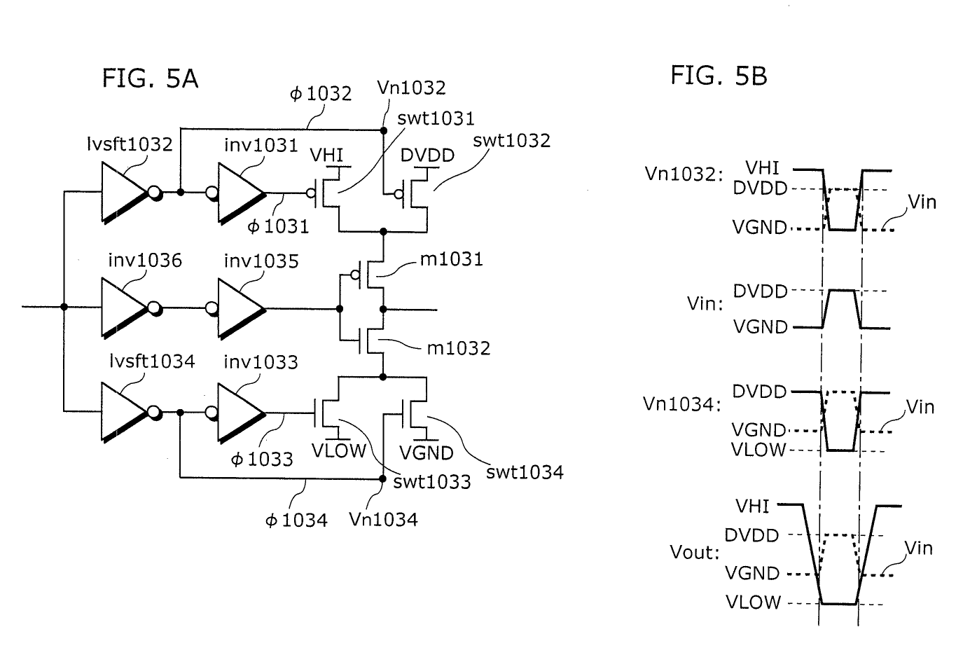

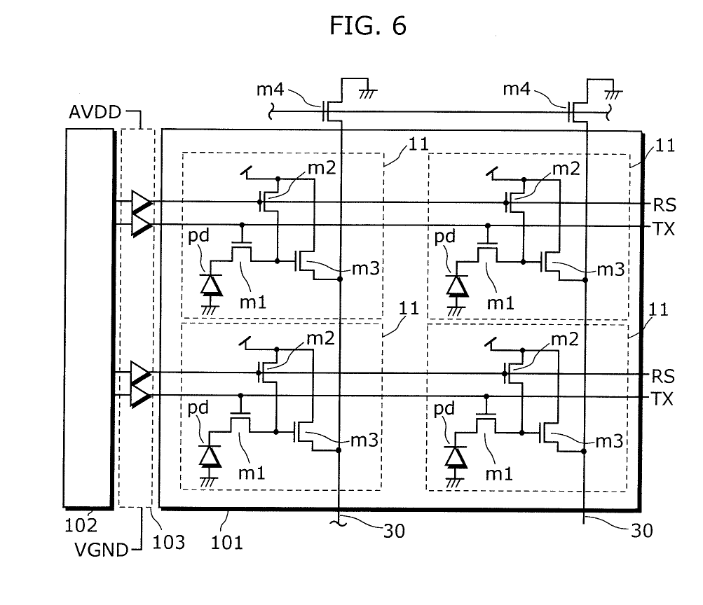

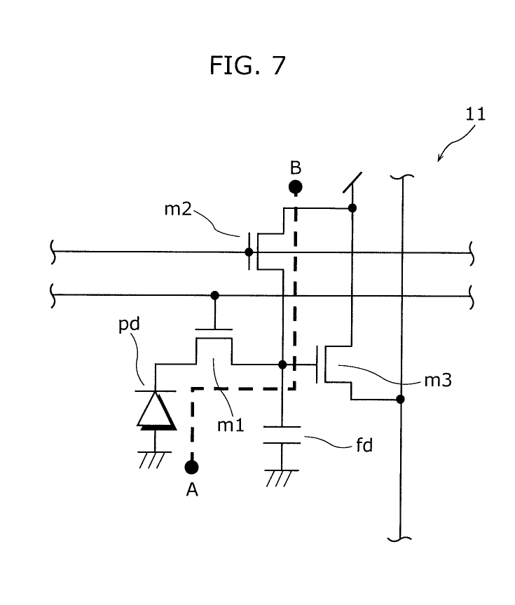

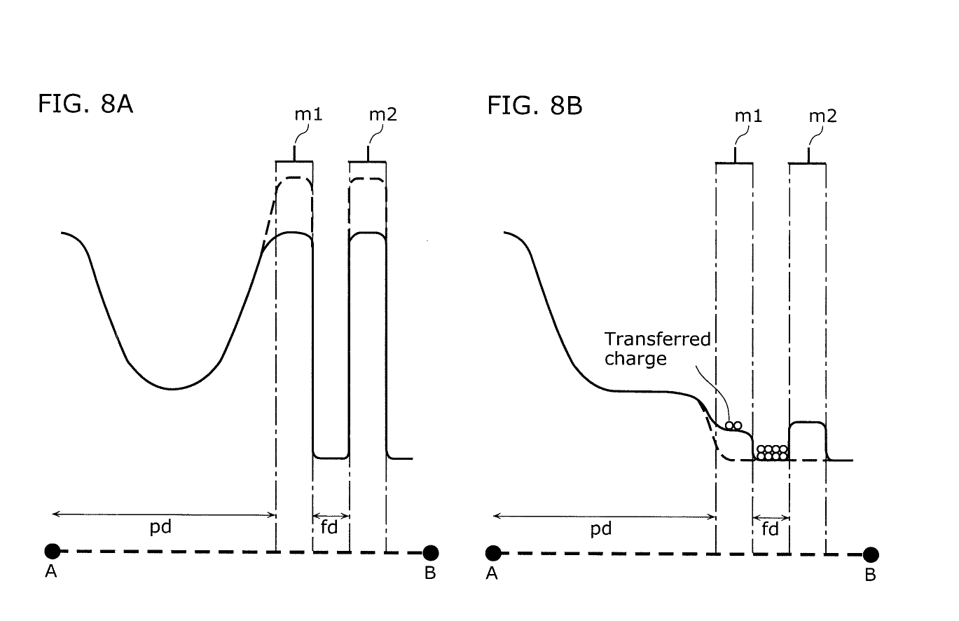

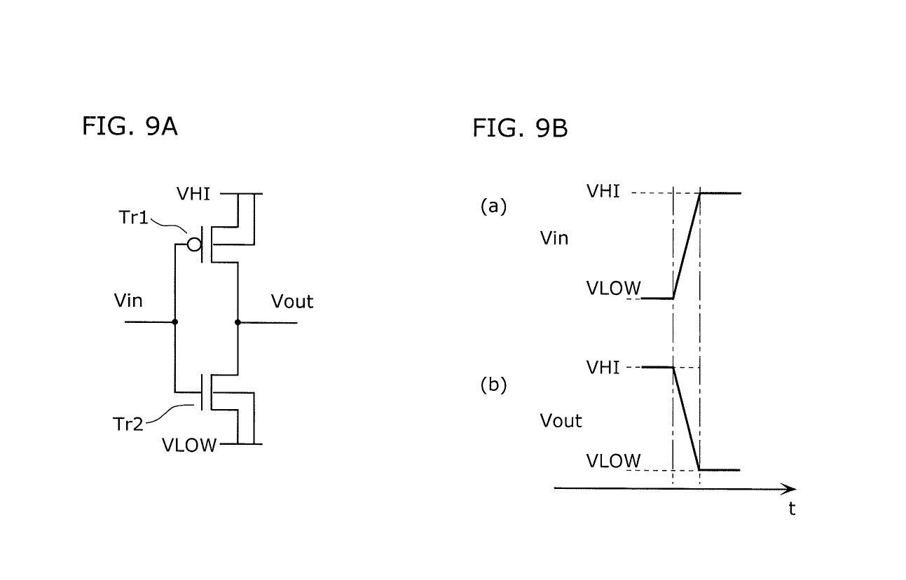

FIG. 5A shows a specific structure of the drive circuit 203 in the second example. FIG. 5B shows the potential of the output signal Vout, the input signal Vin in the drive circuit 203, and the nodes Vn 1032 and Vn 1034.

In the drive circuit 203, the drive inverter which drives each transistor in the pixel cells 11 is composed of the P-channel transistor m1031 and N-channel transistor m1032, and switch transistors swt1031 to swt1034. The switches sw1031, sw1032, sw1033 and sw1034 in FIGS. 2A to 2C respectively correspond to the switch transistors swt1031, swt1032, swt1033, and swt1034. The drive circuit 203 includes the drive inverter, the inverters inv1031, inv1033, inv1035, and inv1036, and a voltage conversion circuit (inverter-type level shift circuit) lvsft1032 and Ivsft1034.

The gates of the switch transistors swt1031 to swt1034 are connected to the output of the scanning circuit 202, and the pulse control signals from the scanning circuit 202 are input to the gates of the switch transistors swt1031 to swt1034. The inverter inv1031 is inserted between the output of the scanning circuit 202 and the gate of the switch transistor swt1031. The voltage conversion circuit lvsft1032 is inserted between the output of the scanning circuit 202 and the gates of the switch transistors swt1031 and swt1032. The inverter inv1033 is inserted between the output of the scanning circuit 202 and the gate of the switch transistor swt1033. The voltage conversion circuit Ivsft1034 is inserted between the output of the scanning circuit 202 and the gates of the switch transistors swt1033 and swt1034. The inverters inv1035 and inv1036 are respectively inserted between the output of the scanning circuit 202 and the gates of the P-channel transistor m1031 and the N-channel transistor m1032.

The drive circuit 203 is different from the drive circuit 203 in the first example in that the pulse control signal (input signal Vin) is used as the pulse control signals ◯1031 to 1034 for the switch transistors swt1031 to swt1034. In the drive circuit 203, the switch transistors swt1031 and swt1032 switches between “VHI” and “DVDD” to be supplied to the source of the P-channel transistor m1031 based on the pulse control signal, and the switch transistors swt1033 and swt1034 switches between “VLOW” and “VGND” to be supplied to the source of the N-channel transistor m1032. As a result, control of the power source switches in the drive inverters, in other words, control for switching the switch transistors swt1031 to swt1034 on and off, is performed using the pulse control signal (input signal Vin) to the pixel cells 11. It is preferable to control the circuit operation with the small number of pulse control signals as much as possible, since having many control signal lines lead to increased chip area caused by the increase in the wiring and the circuit size and increased number of the chip terminals.

Usually, the pulse control signals are generated by providing a timing generator such as FPGA outside the chip to input the pulse control signals to the sensor chip, or by providing the timing generator within the chip to generate the pulse control signals. The generated pulse control signal is input to the column scanning circuit and the row scanning circuit, and desired column or row of the pixel cells 11 is selected. The drive circuit 203 amplifies the current corresponding to the selected row or column of the pixel cells 11, and inputs the amplified current to the pixel cells 11. Generally, the power source voltage DVDD for digital circuits which is lower in voltage level than the power source voltage AVDD for analog circuits and the ground voltage DVGND are used for generating the pulse control signal (input signal Vin) by the timing generator in the chip, for generating the pulse control signal (input signal Vin) input to the chip, and processing signals in the column scanning circuit and the row scanning circuit.

There is a possibility that the switch transistors swt1031 to swt1034 are not fully switched off if the voltage level of the pulse control signals ◯1031 to ◯1034 supplied to the gates of the switch transistors swt1031 to swt1034 are properly set. When supplying the pulse control signal from outside the sensor chip, the levels of Hi voltage and Low voltage of the pulse control signal (input signal Vin) may be determined at any value. Accordingly, it is possible to set the Hi voltage and the Low voltage of the pulse control signal (input signal Vin) at a voltage level where the switch transistors swt1031 to swt1034 are fully switched off, and input set signal, and generate the pulse control signals ◯1031 to 1034 using inputted signal.

However, in recent years, in terms of low power consumption, the power source voltage DVDD for digital circuits that is lower than the power source voltage AVDD for analog circuit that requires relatively higher voltage is generally used for digital circuits composed of logic circuits. Thus, the power source voltage DVDD for digital circuits is used in the column scanning circuit and the row scanning circuit which select columns and rows of the pixel cells 11.

As described above, the column scanning circuit and the row scanning circuit select the columns and rows of the desired pixel cells 11, and the control signal pulse (input signal Vin) is input to the drive circuit 203. Here, the voltage level of the control signal pulse (input signal Vin) is DVDD for Hi voltage, and VGND for Low voltage. Usually the pulse control signal (input signal Vin) is converted to a voltage level to input the pixel cells 11, and the converted voltage is input to the pixel cells 11. However, as described above, voltage conversion cannot be performed with the conventional method when the voltage range of the pulse control signal (output signal Vout) exceeds a certain level.

In order to solve the problem above, the drive circuit 203 according to the second example controls the power source switches in the drive inverter using the pulse control signal (input signal Vin) output from the scanning circuit 202 and input to the pixel cells 11. For that purpose, the voltage conversion circuits Ivsft1032 and Ivsft1034 which performs voltage conversion on the pulse control signal (input signal Vin) output from the scanning circuit 202 and input to the pixel cells 11 to a voltage level where the switch transistors swt1031 to 1034 are fully switched off are provided. Providing the voltage conversion circuits lvsft1032 and lvsft1034 allows generating the pulse control signals ◯1031 to 1034 that control the switch transistors swt1031 to swt1034 within the drive circuit 203. Thus, it is not necessary to input multiple pulse control signals from outside the drive circuit 203, and the power source voltage such as VHI and VLOW may only have to be input.

Furthermore, when the imaging area 201 is larger than a certain size, the control signal lines for driving the pixel cells 11 is long as well, and the number of transistors to be driven increase when the number of pixel cells 11 increases. This increases the load on the drive circuit 203 to be driven. In order to drive the increased load, the drive circuit 203 has to supply more current. This increases the size of the transistors composing the drive circuit 203. When the transistor size increases, the current amount of signal input to the gate needs to be amplified in order to drive the parasitic capacitance to the transistor. In order to solve the problem, in the drive circuit 203 in the second example, the inverters inv1035 and inv1036 are provided in order to drive the gate capacitances of the P-channel transistor m1031 and N-channel transistor m1032.

With the circuit above, control of the power source switch in the drive inverter is performed using the pulse control signal (input signal Vin) generated using the power source voltage DVDD for digital circuits. With this, it is possible to reduce the number of control signal line dedicated for controlling the switch and the number of chip terminals. Thus, the area of the chip can be reduced. Furthermore, low power consumption can be achieved since the pulse control signal using the power source voltage for digital circuits is available until the drive circuit 203, which is immediately before the pixel cells 11. Therefore, it is possible to implement the image sensor having high image quality with low power consumption and small chip area.

As described above, according to the drive circuit 203 in the second example, it is possible to expand the voltage range of the pulse control signal that can be applied to the pixel cells 11 without applying the voltage exceeding the maximum rated voltage between the terminals of the transistors to any transistor, as in the drive circuit 203 in the first example.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to the solid-state imaging device, and particularly to digital cameras and others.

What is claimed is:

1. A solid-state imaging device comprising:
pixels which are arranged in rows and columns, and each of which includes a photodiode;
column signal lines which are provided corresponding to the columns of said pixels, and each of which transmits, in a column direction, a pixel signal corresponding to a charge generated in each of the photodiodes;
a generating unit configured to drive said pixels and to generate a control signal for outputting the pixel signal from said pixels to said column signal lines;
a drive unit configured to drive the control signal generated by said generating unit; and
a control signal line which connects said drive unit and said pixels, and supplies the control signal driven by said drive unit to said pixels,
wherein said drive unit includes:
a first P-channel transistor and a first N-channel transistor which include gates connected to an output of said generating unit, and which include drains that are connected to each other, and a connecting point of the drains is connected to said control signal line;
a first switch which switches between first power and second power to be supplied to a source of said first P-channel transistor; and
a second switch which switches between third power and fourth power to be supplied to a source of said first N-channel transistor.

2. The solid-state imaging device according to claim 1,
wherein said first switch switches between the first power and the second power to be supplied to the source of said first P-channel transistor based on the control signal, and
said second switch switches between the third power and the fourth power to be supplied to the source of said first N-channel transistor based on the control signal.

3. The solid-state imaging device according to claim 2,
wherein said first switch includes:
a second P-channel transistor which has a source connected to the first power and which has a drain connected to the source of said first P-channel transistor; and
a third P-channel transistor which has a source connected to the second power and which has a drain connected to the source of said first P-channel transistor, and
said second switch includes:
a second N-channel transistor which has a source connected to the third power and which has a drain connected to the source of said first N-channel transistor; and
a third N-channel transistor which has a source connected to the fourth power and which has a drain connected to the source of said first N-channel transistor.

4. The solid-state imaging device according to claim 3,
wherein gates of said second and third P-channel transistors are respectively connected to an output of said generating unit, and
said drive unit further includes
a first signal voltage conversion element inserted between the output of said generating unit and the gates of said second and third P-channel transistors.

5. The solid-state imaging device according to claim 3,
wherein gates of said second and third N-channel transistors are respectively connected to an output of said generating unit, and
said drive unit further includes
a second signal voltage conversion element inserted between an output of said generating unit and the gates of said second and third N-channel transistors.

6. The solid-state imaging device according to claim 3,
wherein said drive unit further includes
a third signal voltage conversion element inserted between an output of said generating unit and the gates of said first N-channel transistor and said first P-channel transistor.

7. The solid-state imaging device according to claim 3,
wherein gates of said second and third P-channel transistors are respectively connected to an output of said generating unit, and
said drive unit further includes
an inverter element inserted between the output of said generating unit and the gate of said second P-channel transistor.

8. The solid-state imaging device according to claim 3,
wherein gates of said second and third N-channel transistors are respectively connected to an output of said generating unit, and
said drive unit further includes
an inverter element inserted between the output of said generating unit and the gate of said second N-channel transistors.

9. The solid-state imaging device according to claim 3,
wherein said drive unit further includes an inverter element inserted between the output of said generating unit and the gates of said first N-channel transistor and said first P-channel transistors.

10. The solid-state imaging device according to claim 1,
wherein said first switch includes:
a second P-channel transistor which has a source connected to the first power and which has a drain connected to the source of said first P-channel transistor; and
a third P-channel transistor which has a source connected to the second power and which has a drain connected to the source of said first P-channel transistor, and
said second switch includes:
a second N-channel transistor which has a source connected to the third power and which has a drain connected to the source of said first N-channel transistor; and
a third N-channel transistor which has a source connected to the fourth power and which has a drain connected to the source of said first N-channel transistor.
